(19) United States
(12) Patent Application Publication
(10) Pub. No.: US 2023/0077088 A1
(43) Pub. Date: Mar. 9, 2023

(54) METHOD OF FORMING AN UNDERLAYER FOR EXTREME ULTRAVIOLET (EUV) DOSE REDUCTION AND STRUCTURE INCLUDING SAME

(71) Applicant: ASM IP Holding B.V., Almere (NL)

(72) Inventors: Arpita Saha, Espoo (FI); David de Roest, Leuven (BE); Michael Givens, Oud-Heverlee (BE); Charles Dezelah, Helsinki (FI); Monica Thukkaram, Gent (BE); Daniele Piumi, Etterbeek (BE)

(21) Appl. No.: 17/900,065

(22) Filed: Aug. 31, 2022

Related U.S. Application Data
(60) Provisional application No. 63/240,664, filed on Sep. 3, 2021.

(51) Int. Cl. G03F 1/22

(52) U.S. Cl. CPC G03F 1/22

(57) ABSTRACT

Methods of forming structures including a photoresist absorber layer and structures including the absorber layer underlying an extreme ultraviolet (EUV) photoresist are disclosed. Exemplary methods include forming the photoresist absorber layer or underlayer with an oxide of a high atomic number (z) element having an EUV cross section (σ_{α}) of greater than 2×10⁶ cm²/mol and then forming the EUV photoresist over the high-z underlayer.

### CROSS-REFERENCE TO RELATED APPLICATIONS

This application claims priority to U.S. Provisional Patent Application Ser. No. 63/240,664 filed Sep. 3, 2021, titled METHOD OF FORMING AN UNDERLAYER FOR EXTREME ULTRAVIOLET (EUV) DOSE REDUCTION AND STRUCTURE INCLUDING SAME, the disclosure of which is hereby incorporated by reference in its entirety.

### FIELD OF INVENTION

The present disclosure generally relates to structures and to methods used in the formation of devices. More particularly, the disclosure relates to structures including or formed using a photoresist absorber layer (sometimes referred to as an underlayer or UL) with improved extreme ultraviolet (EUV) absorbance to facilitate EUV dose reduction and to methods of forming such structures.

### BACKGROUND OF THE DISCLOSURE

During the manufacture of electronic devices, fine patterns of features can be formed on a surface of a substrate by patterning the surface of the substrate and etching material from the substrate surface using, for example, gas-phase etching processes. As a density of devices on a substrate increases, it generally becomes increasingly desirable to form features with smaller dimensions.

Photoresist is often used to pattern a surface of a substrate prior to etching. A pattern can be formed in the photoresist by applying a layer of photoresist to a surface of the substrate, masking the surface of the photoresist, exposing the unmasked portions of the photoresist to radiation, such as ultraviolet light, developing the exposed or unexposed portions of the photoresist to remove a portion (e.g., the unmasked or masked portion) of the photoresist, while leaving a portion of the photoresist on the substrate surface.

Recently, techniques have been developed to use extreme ultraviolet (EUV) wavelengths to develop patterns having relatively small pattern features. One limitation of methods using EUV is the relatively low flux of EUV photons and the resultant long exposure times and/or the inadequate exposure of the photo-sensitive materials that are responsible for creating contrast between exposed and unexposed areas of the photoresist.

Accordingly, structures for lowering EUV dose requirements and methods of forming such structures are desired. Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to structures including improved photoresist absorber layers (sometimes referred to as underlayers) and to methods of forming the layers and structures. While the ways in which various embodiments of the present disclosure address drawbacks of prior methods and structures are discussed in more detail below, in general, various embodiments of the disclosure provide structures that include a photoresist absorber layer with relatively high EUV sensitivity. The relatively high sensitivity allows for use of a relatively low dosage of EUV to obtain desired contrast between exposed and unexposed areas of the photoresist, which, in turn, allows for the formation of features with desired properties, such as small critical dimensions, which can be formed in a relatively cost-effective manner. In addition, only needing a relatively low dosage of EUV advantageously allows reducing exposure times, thereby increasing throughput of EUV exposures.

Exemplary EUV absorber layers or underlayers include an element with relatively high EUV absorption. In some embodiments, an oxide of such an element (or a metal oxide) is formed, which can be used as an EUV absorption-enhancing underlayer for EUV lithography, for example. Such absorber layers can be stand alone or part on an underlayer film stack. Use of such absorber layers can provide desired patterned features during EUV photoresist patterning, using relatively low EUV dosage during a step of exposing the photoresist to EUV radiation. Exemplary underlayers, e.g., oxides of high-z elements such as I, Te, Cs, Sb, Sn, In, Bi, Ag, Pb, Au, Pt, and Ir (with oxides of Sn or In being desirable in some implementations), can be formed using a cyclical process, such as atomic layer deposition (ALD) or plasma-enhanced atomic layer deposition, which allows for precise control of a thickness of the photoresist absorber layer—both on a surface of a substrate and from substrate to substrate.

The underlayers are primarily based on an oxide of an element having a high (e.g., 45 or higher) atomic number (z), but the underlayers may also be doped with other high z elements (which may be chosen for having a photoabsorption cross section at 91.5 eV on a per mole basis less than 5×10⁶ cm²/mol (or relatively high EUV sensitivity on a molar basis) and/or with lighter elements (which may be chosen for having a photoabsorption cross section at 91.5 eV on a per mass basis greater than 8×10⁵ cm²/g (or relatively high EUV sensitivity on a mass basis)).

In accordance with exemplary embodiments of the disclosure, a method is provided for forming an extreme ultraviolet (EUV) absorber layer on a surface of a substrate. The method includes providing a substrate within a reaction space of a gas-phase reactor, providing a precursor to the reaction space, and providing a reactant to the reaction space. The method also includes the step of forming an absorber layer on a surface of the substrate within the reaction space, and the absorber layer includes an element having an EUV cross section (σ_{α}) of greater than 2×10⁶ cm²/mol. In other embodiments, the precursor includes a compound according to the following formula: MR, where M is selected from Cs, Sb, Sn, In, Bi, Ag, Pb, Au, Pt, and Ir, wherein R is a C1 to C4 alkyl, and where n is from at least 3 to at most 5.

According to some embodiments of the method, the absorber layer further includes a dopant selected from the group consisting of I, Te, Cs, Sb, Sn, In, Bi, Ag, Pb, Au, Pt, and I or from the group consisting of I, Te, Cs, Sb, In, Bi, Ag, Pb, Au, Pt, and I. In these or other cases, the absorber layer further includes a dopant selected from the group consisting of Mn, Fe, Co, Ni, Cu, Zn, Ga, Ge, Hf, and As. In these implementations, the absorber layer includes an underlayer and a layer including the dopant overlying or underlying the underlayer.

The step of forming the absorber layer may include a cyclical deposition process. The step of forming the absorber layer may involve atomic layer deposition. The method also may include forming an EUV photoresist layer overlying the absorber layer. In these or other embodiments, the method may include the step of forming an adhesion layer overlying the absorber layer to limit outgassing from the adhesion layer and facilitate adhesion of the absorber layer to the EUV photoresist layer.

According to other aspects of the description, a structure is provided for forming patterned features using extreme ultraviolet (EUV) radiation. The structure may include a substrate and an absorber layer formed overlying the substrate. The absorber layer may include an oxide of I, Te, Cs, Sb, Sn, In, Bi, Ag, Pb, Au, Pt, or Ir. The structure may also include an EUV photoresist layer formed overlying the absorber layer. In some embodiments of the structures, the absorber layer includes tin oxide or indium oxide.

In these or other embodiments of the structure, the absorber layer includes a dopant selected from the group consisting of I, Te, Cs, Sb, Sn, In, Bi, Ag, Pb, Au, Pt, and (or, in some cases, the group consisting of Ir I, Te, Cs, Sb, In, Bi, Ag, Pb, Au, Pt, and I) and/or from the group consisting of Mn, Fe, Co, Ni, Cu, Zn, Ga, Ge, Hf, and As. The structure may also include a dopant layer underlying or overlying the absorber layer. The dopant layer may include at least one element selected from the group consisting of I, Te, Cs, Sb, Sn, In, Bi, Ag, Pb, Au, Pt, and Ir and/or may include at least one element selected from the group consisting of Mn, Fe, Co, Ni, Cu, Zn, Ga, Ge, Hf, and As. Additionally, the structure may include an adhesion layer overlying the absorber layer to limit outgassing from the adhesion layer and facilitate adhesion of the absorber layer to the EUV photoresist layer.

In accordance with further examples of the disclosure, a system is provided. The system can be used to perform a method described herein and/or to form a structure as described herein.

These and other embodiments will become readily apparent to those skilled in the art from the following detailed description of certain embodiments having reference to the attached figures; the invention not necessarily being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a structure in accordance with exemplary embodiments of the disclosure.

FIG. 3 illustrates a system configured for executing a method as described herein.

FIG. 4 is a graph showing EUV exposure doses (or exposure energy) during testing of an underlayer of the present description including a tin oxide.

FIG. 5 is a graph showing EUV exposure doses (or exposure energy) during testing of an underlayer of the present description including an indium oxide.

FIG. 6 is a side view of an underlayer stack used to provide a dopant to enhance EUV sensitivity showing a sandwich approach.

FIG. 7 is a side view of another underlayer stack used to provide dopants to enhance EUV sensitivity using a laminate mix approach.

FIG. 8 illustrates a direct plasma system for executing a method as described herein.

FIG. 9 illustrates an indirect plasma system for executing a method as described herein.

FIG. 10 illustrates a remote plasma system for executing a method as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of the present invention provided below is merely exemplary and is intended for purposes of illustration only; the following description is not intended to limit the scope of the invention disclosed herein. Moreover, recitation of multiple embodiments having stated features is not intended to exclude other embodiments having additional features or other embodiments incorporating different combinations of the stated features.

The present disclosure generally relates to methods of forming structures that include an extreme ultraviolet (EUV) absorber layer (or underlayer (UL)) and to structures including the EUV absorber layer. Exemplary methods can be used to form structures with underlayers (absorber layers) with increased EUV sensitivity, which can result in lower EUV dosages used during photoresist exposure steps. The methods can be used to form structures with EUV absorber layers that allow for formation of patterned features with desired properties, such as small critical dimensions, reduced tapering and/or reduced roughness, compared to photoresist features formed using typical EUV photolithography techniques. Thus, methods described herein can provide for increased throughput of the manufacture of structures, reduced costs associated with the formation of the structures and/or devices formed using the structures, and/or a reduction of critical dimensions of features formed using the absorber layer and the photoresist layer.

As used herein, the term substrate may refer to any underlying material or materials including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application and can include, for example, a hardmask, such as a metal hardmask, an oxide hardmask, a nitride hardmask, a carbide hardmask, or an amorphous carbon hardmask. Further, the substrate can additionally or alternatively include various features, such as recesses, lines, and the like formed within or on at least a portion of a layer of the substrate.

In some embodiments, film refers to a layer extending in a direction perpendicular to a thickness direction. In some embodiments, layer refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, gas may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as a noble gas.

As used herein, Cp stands for cyclopentadienyl, Me stands for methyl, Et stands for ethyl, Bu stands for butyl, and iPr stands for isopropyl.

In some cases, such as in the context of deposition of material, the term precursor can refer to a compound or compounds that participates in the chemical reaction that produces another compound, and particularly to a compound that constitutes a film matrix or a main skeleton of a film, whereas the term reactant can refer to a compound, in some cases other than precursors, that reacts with the precursor, activates the precursor, modifies the precursor, or catalyzes a reaction of the precursor; a reactant may provide an element (e.g., a halide) to a film and become a part of the film. In some cases, the terms precursor and reactant can be used interchangeably. The term inert gas refers to a gas that may or may not take part in a chemical reaction and/or a gas that does interact with a precursor and/or reactant when, for example, a plasma is formed, but unlike a reactant, it may not become a part of a film matrix to an appreciable extent.

The term cyclic deposition process or cyclical deposition process may refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component. In other cases, the processing techniques may include a plasma process such as plasma enhanced CVD (PECVD) or plasma enhanced ALD (PEALD), which may be preferred in some implementations because they allow working at lower temperatures. Plasma processes may be desirable as they use chemical precursors, such as in thermal ALD, but these processes also cycle an RF-plasma creating the necessary chemical reactions in a highly controlled manner.

The term atomic layer deposition may refer to a vapor deposition process in which deposition cycles, typically a plurality of consecutive deposition cycles, are conducted in a process chamber. The term atomic layer deposition, as used herein, is meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term purge or purging may refer to a procedure in which gas flow is stopped or a procedure involving continual provision of a carrier gas whereas precursor flow is intermittently stopped. For example, a purge may be provided between a precursor pulse and a reactant pulse, thus avoiding, or at least reducing, gas phase interactions between the precursor and the reactant. It shall be understood that a purge can be effected either in time or in space or both. For example, in the case of temporal purges, a purge step can be used, e.g., in the temporal sequence of providing a precursor to a reactor chamber, providing a purge gas to the reactor chamber, and providing a reactant to the reactor chamber, wherein the substrate on which a layer is deposited does not move. In the case of spatial purges, a purge step can take the form of moving a substrate from a first location to which a precursor is supplied, through a purge gas curtain, to a second location to which a reactant is supplied.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, etc. in some embodiments. Further, in this disclosure, the terms including, constituted by and having can refer independently to typically or broadly comprising, comprising, consisting essentially of, or consisting of in some embodiments. Further, the term comprising can include consisting of or consisting essentially of. In accordance with aspects of the disclosure, any defined meanings of terms do not necessarily exclude ordinary and customary meanings of the terms.

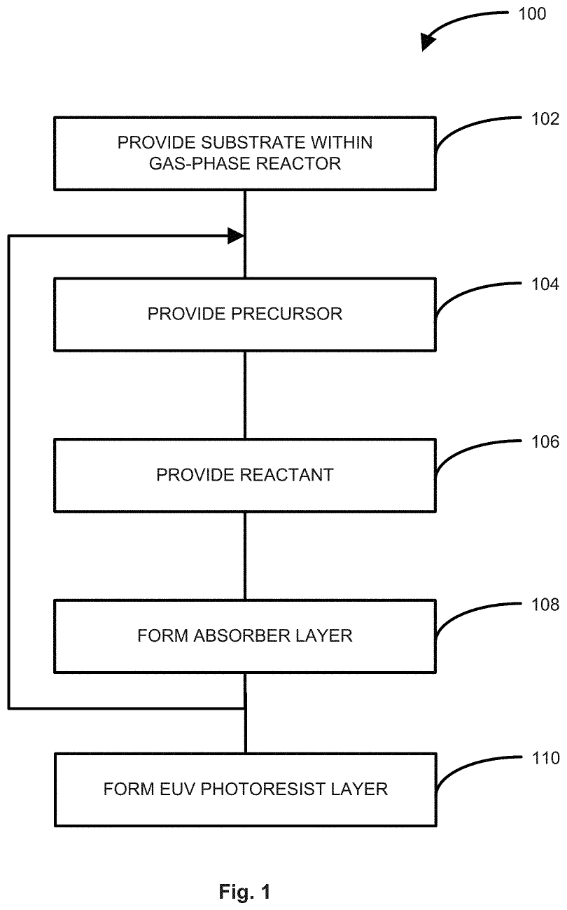

Turning now to the figures, FIG. 1 illustrates a method 100 in accordance with exemplary embodiments of the disclosure. Method 100 can be used for forming an extreme ultraviolet (EUV) absorber layer or underlayer on a surface of a substrate. Method 100 includes the steps of providing a substrate within a reaction space of a gas-phase reactor (step 102), providing a precursor to the reaction space (step 104), providing a reactant to the reaction space (step 106), and forming an absorber layer (step 108). Method 100 can also include a step of forming an EUV photoresist layer (step 110) overlying the absorber layer.

Exemplary methods can be or include cyclical deposition methods, such as ALD methods, and can include, in some useful embodiments, indirect, direct, and remote plasma methods, which may include super cycle processes in which sub-cycles may be selectively repeated to enhance tuning (e.g., to achieve a desired amount or concentration of a desired element in the absorber or underlayer or the like). The high-z underlayers described herein can be formed using CVD, thermal ALD, PECVD, or PEALD. The steps 104, 106, and 108 may be performed contemporaneously in some desirable implementations of the method 100 and/or in differing orders. For example, the steps of exposing the substrate to precursor and reactant may be performed either in an alternating or simultaneous manner, and this results in absorber formation such that absorber may occur contemporaneously with precursor and reactant exposure.

Step 102 includes providing a substrate, such as a substrate described herein, within a reaction space of a gas-phase reactor. The substrate can include one or more layers, including one or more material layers, to be etched. By way of examples, the substrate can include a deposited oxide, a native oxide, or an amorphous carbon layer to be etched. The substrate can include several layers underlying the material layer(s) to be etched.

During step 104, a precursor is provided to the reaction space. Exemplary precursors can include one or more (e.g., metallic) elements with a relatively high EUV cross section (σ_{α}) greater than 2×10⁶ cm²/mol. For example, the precursor can include I, Te, Cs, Sb, Sn, In, Bi, Ag, Pb, Au, Pt, Ir, or the like. The method 100 may be performed to create an underlayer based on a metal oxide, with oxides of elements such as Sn, In, and the like being useful in some embodiments of method 100. In some embodiments, the precursor includes a compound according to the following formula: M(NR¹R²)ₙ, where M is selected from Cs, Sb, Sn, In, Bi, Ag, Pb, Au, Pt, and Ir or from the group consisting of Cs, Sb, In, Bi, Ag, Pb, Au, Pt, and Ar, where R₁ and R2 are independently selected from H and C1 to C4 alkyl, and where n is from at least 3 to 5. In other exemplary embodiments, the precursor includes a compound according to the following formula: MRₙ, wherein M is selected from Cs, Sb, Sn, In, Bi, Ag, Pb, Au, Pt, and Ir, where R is a C1 to C4 alkyl, and where n is from at least 3 to at most 5.

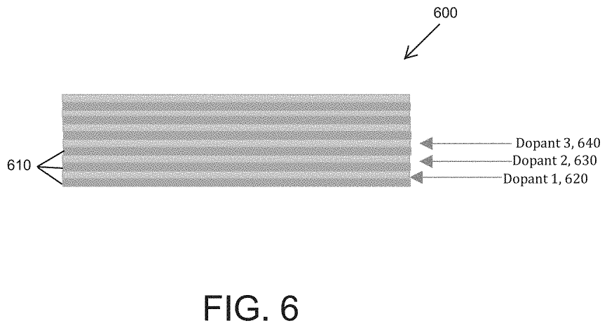

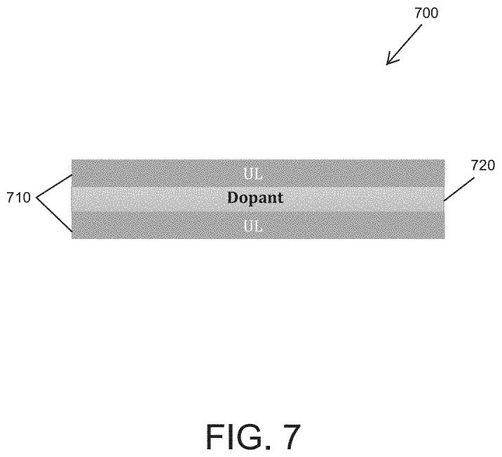

By way of particular examples, the precursor can include one or more a precursor comprising one or more alkylamine ligands such as tetrakis(diethylamino)tin, a precursor comprising one or more metal beta-diketonate ligands, a precursor comprising one or more alkoxide ligands, a precursor comprising one or more amidinate ligands, a precursor comprising one or more alkyl ligands, a precursor comprising one or more hydrogen ligands, a precursor comprising a combination of hydrogen and alkyl ligands such as 1H, 3 alkyl ligands (e.g., when the absorber layer includes an oxide of Sn), a precursor comprising cyclopendanienyl (Cp) ligands, and a precursor comprising one or more alkylaminopropoxide ligands, such as dimethylaminopropoxide ligands (e.g., when the absorber layer includes an oxide of In), a precursor comprising one or more halide ligands such as SbCl₃, and a precursor comprising one or more alkylsilyl ligands such as Te(TMS)₂ (e.g., when a dopant of SbTe is deposited above or below the absorber layer as discussed below with reference to FIGS. 6 and 7), or the like.

In some implementations of the method 100, the precursors may comprise ligands including cyclopentadienyl, alkylamide, alkoxide, alkyl, alkylsylyl, halide, amidinate, diazadiene, and carbonyl ligands. In some cases, the metal precursor comprises an alkylamido compound. Exemplary metal alkylamido compounds include a metal center and one or more independently selected (e.g., C1-C4) alkyl amine ligands. Particular examples include M(NMe₂)₄, M(NEt₂)₄, and M(NEtMe)₄.

Exemplary metal alkoxide compounds include M(OMe)₄, M(OEt)₄, M(OiPr)₄, M(OtBu)₄, MO(OMe)₃, MO(OEt)₃, MO(OiPr)₃, and MO(OtBu)₃. Additional metal alkoxide compounds include variations of these compounds, where other alkoxy ligands are used.

Exemplary metal cyclopentadienyl compounds include MCp₂Cl₂, MCp₂, and MCp₂(CO)₄. Additional exemplary cyclopentadienyl compounds include variations of these compounds, where Cp is either unsubstituted or bearing one or more alkyl groups, e.g., MeCp, EtCp, iPrCp, and the like.

By way of particular examples, the precursor can include one or more of a metal halide, such as a Pb halide (e.g., PbF₂), a Sb halide (e.g., SbCl₃), a Bi halide (e.g., BiCl₃, BiF₃, BiI₃), an indium halide (e.g., InF₃, InCl₃); a metal silylamide, e.g., a metal bis(trimethylsilyl)amide (btsa) (e.g., Pb-silylamide (e.g., Pb(btsa)₂)), a Bi-silylamide (e.g., Bi(btsa)₂); a metal trimethylsily precursor (e.g., Te(TMS)₂); a metal alkoxide (e.g., cesium tert-butoxide (CsO^{t}Bu), a Bi-alkoxide, antimony(III) ethoxide (Sb(OEt)₃); a metal amine or amino precursor, such as Bi(NMe₂)₃, Bi(NEtMe)₃), Sb(NMe₂)₃, Pb[N(SiMe₃)₂]₂; a metal cyclopentadienyl precursor (e.g., InCp); an alkyl metal precursor, such as trimethylindium (TMI), triethylindium (TEI), or the like.

By way of additional examples, a metal alkylsilylamide or metal silylamide compound can be represented by the general formula (i), where R1-R6 are each independently selected from a C1-C4 alkyl group.

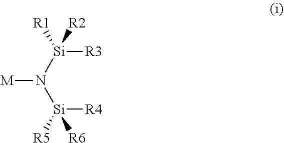

A wide variety of Sn precursors may be utilized. For example, the precursor may be a halide such as SnCl₄, SnBr₄, or SnI₄. In other cases, the precursor may be an alkoxide such as Sn(OR)₄, where R can be independently any of the following: methyl, ethyl, n-propyl, isopropyl, n-butyl, sec-butyl, isobutyl, and tert-butyl. In other exemplary embodiments, the precursor may be an alkylamide such as Sn(NR₂)₄, where R can be independently any of the following: methyl, ethyl, n-propyl, isopropyl, n-butyl, sec-butyl, isobutyl, tert-butyl, trimethylsilyl, triethylsilyl, or Sn(NR₂)₂, where R can be independently trimethylsilyl or triethylsilyl. The precursor may also be an alkyl such as SnR₄, SnHR₃, SnH₂R₂, and SnH₃R, where R can be independently any of the following methyl, ethyl, n-propyl, isopropyl, n-butyl, sec-butyl, isobutyl, tert-butyl, n-pentyl, neopentyl, tert-pentyl, cyclopentyl, n-hexyl, cyclohexyl, phenyl, vinyl, and allyl. A diketonates may also be used such as SnL₂ or SnL₄, where L is a beta-diketonate ligand such as acetylacetonate, 2,2,6,6-tetramethylhexane-3,5-diketonate, 1,1,1,5,5,5-hexafluoroacetylacetonate, and the like. In other cases, the precursor is an amidinates such as Sn(iPr₂FMD)₂, Sn(tBu₂FMD)₂, Sn(iPr₂AMD)₂, and Sn(tBu₂AMD)₂, where FMD is formamidinate and AMD is acetamidinate.

Further, the precursor may take the form of a chelating aminoalkoxides such as Sn(dmap)₂, Sn(dmamp)₂, Sn(dmamb)₂, where R1 is H or Me, and R2-R4 are independently any C1 to C6 hydrocarbyl group and as given by Equation (ii) below and where dmap: R1=H, R2=R3=R4=methyl, dmamp: R1=R2=R3=R4=methyl, or dmamb: R1=ethyl, R2=R3=R4=methyl.

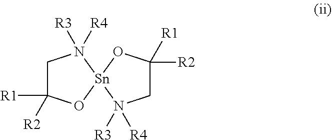

Likewise, a wide variety of Sn precursors may be utilized. For example, the precursor may be a halide such as InCl₃, InCl, InClMe₂, or InBr₃. An alkyls may be used such as InMe₃, InEt₃, InEtMe₂, Me₂In(CH₂)₃NMe₂, In(N(SiMe₃)₂)Et₂, In(N(SiMe₃)₂)Me₂ InMe₂(dmap), InMe₂(dmamp), or InMe₂(dmamb). Diketonates may be used as the In precursor such as InL₃, where L is a beta-diketonate ligand such as acetylacetonate, 2,2,6,6-tetramethylhexane-3,5-diketonate, 1,1,1,5,5,5-hexafluoroacetylacetonate, and the like. The precursor may also be a cyclopentadienes such as InCp, In(EtCp), or indium compounds comprising other alkyl substituted Cp ligands. In other embodiments, the precursor is a chelating aminoalkoxide such as In(dmap)₃, In(dmamp)₃, In(dmamb)₃; InMe₂(dmap), InMe₂(dmamp), InMe₂(dmamb), or In(dmamb)₂(OiPr). Amidinates may be used for the precursor such as In(iPr₂FMD)₃, In(tBu₂FMD)₃, In(iPr₂AMD)₃, and In(tBu₂AMD)₃, where FMD is formamidinate and AMD is acetamidinate.

Additionally, a wide variety of Sb precursors may be utilized. For example, the precursor may be a halide such as SbCl₃, SbCl₅, SbBr₃, or SbI₃. The Sb precursor may be an alkylsilyl such as Sb(SiMe₃)₃ or Sb(SiEt₃)₃. Alkylamides may be used for the Sb precursor such as Sb(NR₂)₃, where R can be independently any of the following: methyl, ethyl, n-propyl, isopropyl, n-butyl, sec-butyl, isobutyl, tert-butyl, trimethylsilyl, and triethylsilyl. Additionally, the Sb precursor may be an alkoxides such as Sb(OR)₃, where R can be independently any of the following: methyl, ethyl, n-propyl, isopropyl, n-butyl, sec-butyl, isobutyl, and tert-butyl.

With regard to Te precursors, the precursor may be a halide such as TeCl₄, TeF₆, TeBr₄, or TeI₄. The precursor may also be an alkyl such as TeR₂ where R can be independently any of the following methyl, ethyl, n-propyl, isopropyl, n-butyl, sec-butyl, isobutyl, tert-butyl, n-pentyl, neopentyl, tert-pentyl, cyclopentyl, n-hexyl, cyclohexyl, phenyl, vinyl, and allyl. An alkylsilyl may be used for the Te precursor such as Te(SiMe₃)₂ or Te(SiEt₃)₂. In some embodiments, the Te precursor may be an alkylgermyl such as Te(GeMe₃)₂ or Te(GeEt₃)₂. Further, the Te precursor may take the form of an alkoxide such as Te(OR)₄, where R can be independently any of the following: methyl, ethyl, n-propyl, isopropyl, n-butyl, sec-butyl, isobutyl, and tert-butyl.

A temperature within a reaction space during step 104 can be, for example, between about 20° C. and about 200° C. A pressure within the reaction chamber during step 104 can be about 140 Pa to about 1300 Pa. A flowrate of the precursor can be between about 200 to about 2000 sccm. A duration of a pulse of introducing the precursor to the reaction chamber can be between about 0.1 and about 15 seconds.

During step 106, a reactant is provided to the reaction space. In accordance with examples of the disclosure, the reactant includes a halide, such as one or more of F, Cl, Br, and I. Particular exemplary halides suitable for use as a reactant include HF, TiF₄, SnI₄, CH₂I₂, HI, I₂, and the like. In some cases, another precursor can be a reactant. In such cases, the reactant can include any of the precursors noted above.

In addition, oxygen reactants, nitrogen reactants, carbon reactants, and reducing reactants may be used. Suitable oxygen reactants include O₂, O₃, and H₂O. Suitable nitrogen reactants include N₂, NH₃, N₂H₂, and forming gas. Suitable carbon reactants include alkyls such as CH₄. Suitable reduction reactants include H₂. If other elements are desired, the reactant may be chosen to suit the need. For example, to Te is desired, one could us Te(OR)₄, Te(TMS)₂, dialkyltellurides (such as Te(iPr)₂, Te(tBu)₂, and the like) or elemental Te, where R stands for an alkyl such as a low C alkyl (e.g., one containing 1 to 4 C atoms), where TMS stands for trimethylsilyl, where TES stands for triethylsilyl (or more broadly for trialkylsilyl), where, for S, one could use H₂S, dialkylsulfide, dialkyldisulfide, alkylthiol, (TMS)₂S, S₂Cl₂, or elemental S, and where, for Se, one could use H₂Se, alkylselenol, dialkylselenide, dialkyldiselenide, bis(trialkylsilyl)selenide, or elemental Se. The precursor may be an acetate such as Sn(OAc)₄ or SnBu₂(OAc)₂, where OAc is the acetate ligand. In some embodiments, the precursory is a cyclic amide of Sn(II) such as (1,3-bis(1,1-dimethylethyl)-4,5-dimethyl-(4R,5R)-1,3,2-diazastannolidin-2-ylidene).

A temperature and pressure within the reaction chamber during step 106 can be the same or similar to the temperature and/or pressure noted above in connection with step 104. A flowrate of the reactant can be between about 100 to about 2000 sccm. A duration of a pulse of introducing the reactant to the reaction chamber can be between about 0.1 and about 30 seconds. As illustrated in FIG. 1, steps 104 and 106 can be repeated one or more times to form the absorber layer (step 108). Various combinations of precursors and corresponding reactants suitable for use in steps 104 and 106 can be used to form the absorber layer. For example, in some cases, the absorber layer includes an oxide, such as a metal oxide of Sn, In, or the like.

In some cases, the absorber layer comprises an oxide of a high-z element (e.g., an element with an atomic number over 45) such as one selected from the group consisting of F, Mg, Na, Al, Mn, Fe, Co, Ni, Cu, Zn, Ga, Ge, and As. In accordance with other examples, the absorber layer is doped (e.g., during step 104, 106, and/or 108) to include a dopant or material useful for increasing the EUV sensitivity. For example, some embodiments of the method 100 include doping the absorber layer with another element with a high atomic number (z), which also has a high EUV absorption on a per mole basis, e.g., a EUV cross section (σ_{α}) greater than 2×10⁶ cm²/mol. These dopants may be selected so as to include one or more of F, Mg, Na, Al, Mn, Fe, Co, Ni, Cu, Zn, Ga, Ge, and As. In these or alternative embodiments of method 100, the dopant may be a lighter element or low-z element that can be chosen due to its relatively high EUV sensitivity on a mass basis (e.g., an element with a photoabsorption cross section at 91.5 eV on a per mass basis greater than 8×10⁵ cm²/g or higher), such as one or more of Mn, Fe, Co, Ni, Cu, Zn, Ga, Ge, and As and with F, Na, Mg, and Al being preferred in some cases.

The absorber layers which are described herein may, for example, be deposited using a thermal cyclical (e.g., ALD) or a thermal CVD method. Alternatively, the absorber layers that are described herein may be deposited using cyclical plasma (e.g., plasma ALD) or plasma pulsed-CVD—e.g., by activating (directly or remotely) a reactant and/or precursor. Both approaches may suitably provide for the deposition of thin (5 nm) absorber layers with low non-uniformity.

Particular examples of materials suitable for the absorber layer are provided above. A thickness of the absorber layer formed during step 104 can be in the range of 1 to 10 nm, with 2 to 5 nm being useful in some cases and with 2 to 3 nm used in some embodiments of structures with a metal oxide underlayer as described herein.

As illustrated in FIG. 1, once a desired thickness of the absorber layer via steps 104-108 is obtained, an optional EUV photoresist layer can be formed over the absorber layer (e.g., in direct contact with the absorber layer) during step 110. In such implementations of the method, the EUV photoresist layer may include any suitable photoresist, such as molecular, metal oxide, or chemically amplified photoresist. In addition, it may be desirable to etch or strip the absorber layer from the substrate surface. Therefore, the absorber layer may desirably include material that can form soluble or volatile compounds when reacted with an etchant.

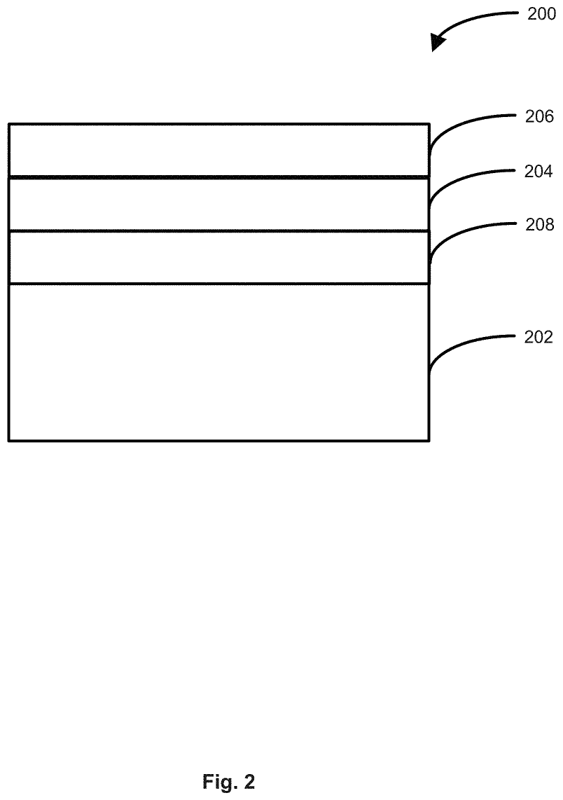

FIG. 2 illustrates a structure 200 in accordance with exemplary embodiments of the disclosure. Structure 200 can be formed using, for example, method 100. As illustrated, structure 200 includes a substrate 202, an absorber layer 204, and optionally one or more of a material layer 208, and a photoresist layer 206. Material layer 208 and EUV photoresist layer 206 can be used to provide desired stability to absorber layer 204 and/or for other reasons. Substrate 202 can include a substrate as described above. By way of examples, substrate 202 can include a semiconductor substrate and can include one or more layers. Further, as noted above, substrate 202 can include various topologies, such as recesses, lines, and the like formed within or on at least a portion of a layer of the substrate.

Absorber layer 204 can include an absorber layer formed in accordance with a method described herein (e.g., method 100) and/or comprise absorber material as described herein and/or have properties as described herein. A thickness of absorber layer 204 can depend on a composition of absorber layer 204, a thickness of and/or composition of material layer 208, a thickness of and/or composition of photoresist layer 206, a type of photoresist, and the like. In accordance with examples of the disclosure, absorber layer 204 has a thickness of less than 10 nm or less than or about 5 nm (such as 2 to 3 nm or more).

Material layer 208 can be formed of, for example, a hard mask. A hard mask can be any layer that provides etch contrast with the underlying layers. A commonly used hard mask is amorphous carbon. In other embodiments, the material layer 208 may include metals, semiconductors and their alloys, oxides, nitrides, and carbides. A thickness of material layer 208 can be from about 0.1 to about 10 nm. Photoresist layer 206 can be formed of, for example, molecular resist, a metal oxide resist, or a chemically amplified resist. A thickness of photoresist layer 206 can be from about 5 to about 40 nm.

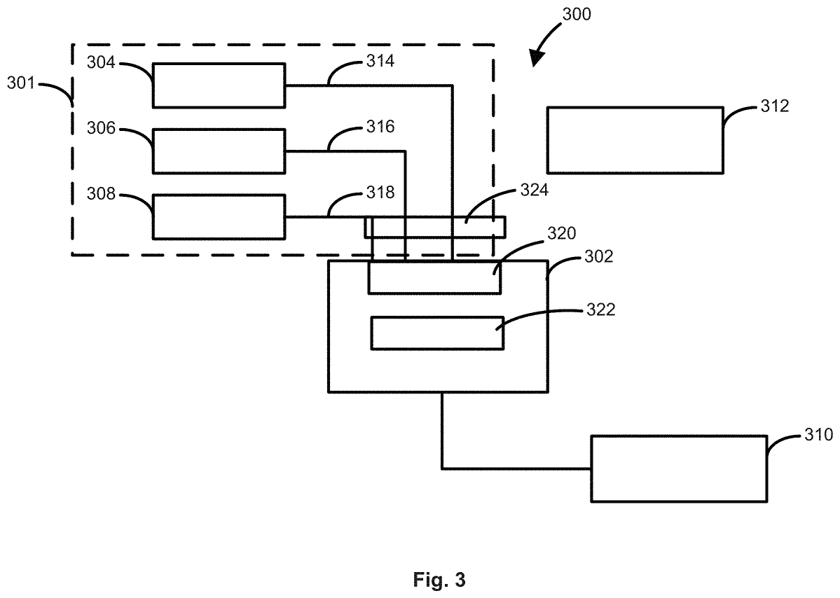

FIG. 3 schematically illustrates a system 300 in accordance with examples of the disclosure. System 300 can be used to perform a method as described herein and/or to form a structure or a portion thereof as described herein. In the illustrated example, system 300 includes one or more reaction chambers 302, a precursor injector system 301, a precursor vessel 304, a reactant vessel 306, an auxiliary reactant source 308, an exhaust source 310, and a controller 312. System 300 may include one or more additional gas sources (not shown), such as an inert gas source, a carrier gas source and/or a purge gas source. Reaction chamber 302 can include any suitable reaction chamber, such as an ALD or CVD reaction chamber as described herein.

Precursor vessel 304 (sometimes a metal precursor vessel) can include a vessel and one or more precursors as described herein including metal precursors—alone or mixed with one or more carrier (e.g., inert) gases. Reactant source vessel 306 can include a vessel and one or more reactants (e.g., oxide reactants, halide reactants, and the like) as described herein— alone or mixed with one or more carrier gases. In some cases, it will be understood that some reactants, such as O₂, N₂, Hz, He, and Ar, are very common and are used throughout a fabrication. Accordingly, they may not be necessarily stored in a vessel inside the tool but may, instead, be provided from a central storage unit (not shown, which may be a pressurized vessel) via gas lines to the tools in the fabrication system 300. Auxiliary reactant source 308 can include an auxiliary reactant or a precursor as described herein. Although illustrated with three source vessels 304-308, system 300 can include any suitable number of source vessels to provide the element with a high EUV absorption on a per mass basis and other materials, such as doping materials, in some implementations. Source vessels 304-308 can be coupled to reaction chamber 302 via lines 314-318, which can each include flow controllers, valves, heaters, and the like. In some embodiments, a vessel is heated so that a precursor or a reactant reaches a desired temperature. Each vessel may be heated to a different temperature, according to the precursor or reactant properties, such as thermal stability and volatility. Exhaust source 310 can include one or more vacuum pumps.

Controller 312 includes electronic circuitry and software to selectively operate valves, manifolds, heaters, pumps, and other components included in system 300. Such circuitry and components operate to introduce precursors, reactants, and purge gases from the respective sources. Controller 312 can control timing of gas pulse sequences, temperature of the substrate and/or reaction chamber 302, pressure within the reaction chamber 302, and various other operations to provide proper operation of the deposition or reactor system 300. Controller 312 can include control software to electrically or pneumatically control valves to control flow of precursors, reactants, and purge gases into and out of the reaction chamber 302. Controller 312 can include modules, such as a software or hardware component, which perform certain tasks. A module may be configured to reside on the addressable storage medium of the control system and be configured to execute one or more processes.

In the illustrated example, system 300 also includes a gas distribution assembly (e.g., a showerhead) 320 and a susceptor or substrate holder 322 (which can include an electrode and/or a heater) for receiving and supporting a substrate (e.g., a wafer). In accordance with some examples of the disclosure, system 300 can also include a remote plasma unit 324 to activate one or more reactants, precursors, and/or inert gases.

Other configurations of system 300 are possible, including different numbers and kinds of precursor and reactant sources. Further, it will be appreciated that there are many arrangements of valves, conduits, precursor sources, and auxiliary reactant sources that may be used to accomplish the goal of selectively and in a coordinated manner feeding gases into reaction chamber 302. Further, as a schematic representation of a deposition system, many components have been omitted for simplicity of illustration, and such components may include, for example, various valves, manifolds, purifiers, heaters, containers, vents, and/or bypasses.

During operation of deposition assembly 300, substrates, such as semiconductor wafers (not illustrated), are transferred from, for example, a substrate handling system to reaction chamber 302. Once substrates are transferred to reaction chamber 302, one or more gases from gas sources, such as precursors, reactants, carrier gases, and/or purge gases, are introduced into reaction chamber 302. In some embodiments, the precursor is supplied in pulses, the reactant is supplied in pulses and the reaction chamber is purged between consecutive pulses of precursor and reactant.

From the above discussion, it should be understood that the inventors were attempting to design new UL materials of high sensitivity for use, for example, in the EUV spectral region in order to improve the EUV absorbance and provide a cost efficient solution. The layers of different elements that have high EUV capture cross sections can be included, in some cases, in the stack to increase the EUV sensitivity.

In this regard, the inventors understood that it may be desirable to provide an underlayer (or absorber layer) under a EUV photoresist layer to reduce the full exposure required or to provide desirable “dose reduction.” Further, the inventors determined that such an underlayer can be provided by forming an underlayer that is based on an oxide of a high-z element, which may be chosen due to its relatively high EUV absorption (e.g., an element having an EUV cross section (σ_{α}) of greater than 2×10⁶ cm²/mol or the like). Generally, this high-z element may be chosen to be one of I, Te, Cs, Sb, Sn, In, Bi, Ag, Pb, Au, Pt, and Ir, with the following description presenting specific useful oxides (e.g., SnOₓ and InOₓ) with the understanding that these teachings can be expanded to other metal oxides.

In one exemplary implementation of the teaching herein, the underlayer is formed to include or be based mainly upon tin oxide. During testing, the SnOₓ layer showed EUV dose reduction even for thinner films (e.g., films with thicknesses of 2 nm and 3 nm or films with a thickness in range of 2 to 5 nm). The precursor used to form the underlayer films on the substrate was tetrakis(diethylamino)tin, and an EUV photoresist was formed over each of the underlayer films.

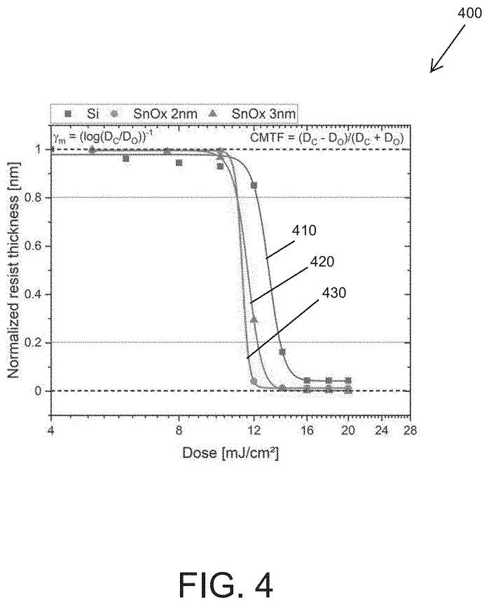

FIG. 4 illustrates a graph 400 showing with lines 410, 420, and 430 EUV doses when an underlayer was provided underlying a EUV photoresist (e.g., a photoresist with a thickness of 35 nm). Particularly, line 410 illustrates measured doses for a reference silicon underlayer while line 420 illustrates doses for a 3 nm thick underlayer of tin oxide and line 430 illustrates doses for a 2 nm thick underlayer. This testing shows a dose reduction for such thinner films can be provided with a high-z underlayer. The exposure dose 420 and 430 at which resist clears SnOₓ shows the shifts left towards lower dose value than reference 410 so lesser dose is required to develop the photoresist. The testing showed full photoresist development, and a smooth and amorphous film surface on the underlayer, which is good for integration. Thinner photoresists (e.g., 40 nm or less with 35 nm used in some testing) have shown better responses, and tin oxide underlayer showed good adhesion and no or little collapse. For example, it may be useful to provide a minimum concentration of Sn in the underlayer in the range of at least 10 to at most 90 atomic percent.

In another exemplary implementation of the teaching herein, the underlayer is formed to include or be based mainly upon indium oxide. During testing, the InOₓ layer showed EUV dose reduction even for thinner films (e.g., films with thicknesses of 2 nm, 4 nm, and 10 nm or films with a thickness in range of 2 to 10 nm). The precursor used to form the underlayer films on the substrate was trimethylindium, and an EUV photoresist was formed over each of the underlayer films.

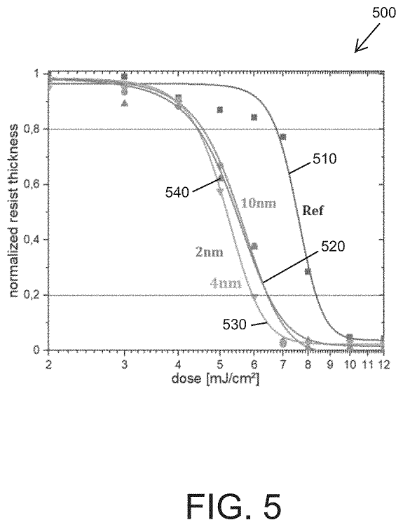

FIG. 5 illustrates a graph 500 showing with lines 510, 520, 530, and 540 EUV doses (e.g., EUV exposure at ILT) when an underlayer was provided underlying a EUV photoresist (e.g., a SEVR photoresist with a thickness of 35 nm). Particularly, line 510 illustrates measured doses for a reference silicon underlayer while line 520 illustrates doses for a 10 nm thick underlayer of indium oxide, line 530 illustrates doses for a 4 nm thick underlayer, and line 540 illustrates doses for a 2 nm thick underlayer.

This testing again shows a dose reduction for such thinner films can be provided with a high-z underlayer. The exposure dose 520, 530, and 540 at which resist clears InOₓ shows the shifts left towards lower dose value than reference 510 so lesser dose is required to develop the photoresist. Work with an underlayer including indium oxide showed a very positive impact with 25 percent dose reductions (e.g., until below 2 nm in some cases). The testing showed full photoresist development, and a smooth and amorphous film surface on the underlayer, which is good for integration. It is believed that it is mainly the top part of the high-z underlayer that contributes to the dose lowering (as the secondary electrons are reabsorbed) such that thinner films can be effectively utilized and are desirable. Particularly, thinner (and amorphous) films can be helpful in etch selectivity so it is beneficial that thinner films such as those tested impact dose reduction. For example, it may be useful to provide a concentration of In in the underlayer that is from 10 to 90 atomic percent, with a 30 atomic percent of In used in one exemplary implementation.

As discussed above, it may be desirable to dope the underlayer to enhance the EUV absorbance. In some embodiments, the new underlayers based on an oxide of a high-z element (e.g., a metal from the listings provided above) may be doped such as with Te, Sb, Sn, In, and the like. In other embodiments, an underlayer that may contain mostly Si, C, and O may be doped to improve EUV absorbance and/or the underlayer may be combined in a sandwich having a thin dopant layer between underlayers. Si and C do not have high EUV absorbance, and O has higher absorbance but not sufficient to provide desired levels of EUV dose requirements.

With these issues with common underlayers in mind, the inventors determined that the photoemission cross sections of different atoms that are higher than those of O (and, therefore, also of Si and C) could be included as a dopant in the underlayer composition to increase the EUV sensitivity. This can be used to provide material absorption at EUV by incorporating elements containing elements or atoms such as Te, Sb, Sn, In, and/or other high-z elements in the underlayer composition. Since the sensitivity is going to be predominantly dictated by the composition and the presence of these high-z materials are an important factor. The composition of these elements can be tuned as desired in the doping mechanism. Providing these elements as dopants provides more freedom in tuning as compared with use of a high-z layer with underlayer stacks. Due to the use of the doping process, the composition can more readily be tuned to achieve a desired increase in EUV sensitivity, and, in some cases, one or more (matching or differing) dopant laminate layers may be used with the underlayer (e.g., with underlayers sandwiching the dopant laminate layer, with dopant laminate layers sandwiching the underlayer, or with stacks of alternating dopant laminate layers and underlayers).

The introduction of high-z elements as dopants in an underlayer (e.g., an underlayer as described above and/or in other underlayers such as ones that are mostly silicon) provided a number of desirable benefits. It can be used to increase the EUV sensitivity of the underlayer, which can reduce the EUV dose required for developing EUV photoresist overlying the underlayer. The dopants, e.g., high-z elements, may be provided as layers (e.g., laminate layers) on one side of or on both sides of (e.g., sandwiching) the underlayer. These doping designs increase compositional tunability of the high-z elements. In some applications, all the steps (e.g., all steps of method 100) can be done in a single reactor, and all steps may be done using a plasma process with no need of thermal and plasma combination processes.

A variety of dopants may be used to increase the EUV sensitivity. In some embodiments, dopants with high EUV absorption may be chosen including one or more of Te, Sb, Sn, In, I, Cs, and Bi. In the same or other embodiments, it may be useful to include dopants with moderate EUV absorption including one or more of Ge, Ni, Cu, Co, Zn, and Hf. The dopant compositions may be provided as a laminate mix (e.g., a Te, Sb, Sn, In, I, Sb, and Te laminate mix) or as oxides (e.g., oxides of Te and Sb or other of the dopant elements).

There are a variety of approaches that can be used to provide the dopants for the underlayer, and the thicknesses of the dopant layer may vary with each approach with the dopant layer thickness range of about 0.3 to 5 nm being useful in some cases. A laminate approach may be used providing one or more dopants, and, in some cases, different dopant concentrations in differing dopant layers, e.g., by changing the sub-cycles in the laminates (such as varying the sub-cycles ratio to main cycles such as 1:1, 1:2, 1:2.5, 1:5, and 1:10). This approach is shown in FIG. 6 with underlayer stack 600 that includes alternating layers of underlayer 610 with dopant layers 620, 630, and 640, which may be similar in composition (and the same or varying thicknesses) or, as shown, may be used to provide three differing dopants or dopant compositions. A bi-layer approach may also be used such as by providing one or more dopants in a layer over or under an underlayer. A sandwich layer approach may be used to provide one or more dopants in a dopant layer that may be sandwiched between two underlayers.

This approach is shown in FIG. 7 with underlayer stack 700 that includes an underlayer 710 sandwiching a dopant layer 720. The doped underlayer or underlayer stack may be provided below the photoresist (as shown in FIG. 2) or may be above the photoresist in some cases or in between two (or more) photoresist layers. Note, the final structure may be either a laminate or a homogenous mixture. Forming a homogenous mixture can include alternatingly depositing layers of composition A and layers of composition B followed by annealing to obtain a homogenous layer that is essentially a mixture of the two layers that were first formed.

The doped underlayer or underlayer stack may be provided in a structure using a number of deposition types including thermal, sputtering, direct plasma, indirect plasma, remote plasma, and radical. In many cases, direct plasma may be a preferred process for forming the underlay or underlayer stack. For example, the underlayer and dopant may be formed using H-plasma or Ar-plasma. In other cases, the underlayer may be formed using H- (or Ar-) plasma while the dopant is formed using Ar- (or H-) plasma. In many cases, an H-containing plasma will also contain Ar, but other noble gasses such as He may be used as well, either as an alternative or in addition to argon. The processing arrangement may be designed as: X (underlayer/purge/H-plasma/purge)+Y (dopant/short purge/H-plasma/purge), with varying of the X:Y ratios (where X is the main cycle and Y is the sub-cycle for doping). In other cases, the processing arrangement may be designed as: X (underlayer/purge/H-plasma/purge)+Y (dopant/short purge/H-plasma/purge), with varying X-Y ratios (where X is the main cycle and Y is the sub-cycle for doping) and then having a top layer of thin underlayer for better uniformity. Separate reactors may be used to deposit the high-z dopant layer and underlayer or the same reactor may be used to deposit them or for doping the underlayer with high-z dopants. Two sources may be used for doping the underlayer and for forming laminates. In other cases, though, three sources may be used in the tool to deposit the high-z layers and then some underlayer (e.g., three precursors SbCl₃, Te(TMS)₂, and underlayer precursors, with SbCl₃ and Te(TMS)₂ used to deposit SbTe as a dopant) or for laminate mix of different dopants.

The presence of high-z materials can lead to outgassing of some volatile products. To address this potential issue, the inventors determined that the outgassing could be prevented or at least reduced by including an adhesion layer in the structures described herein that include high-z materials. For example, the adhesion layer may be provided over the top of the absorber layer 204 of structure 200 in FIG. 2 (and be formed as part of step 108 of method 100 of FIG. 1 or a separate step prior to step 110) or overlying the top layer of underlayer stacks 600 and 700 of FIGS. 6 and 7.

The adhesion layer may be provided as a layer or film of glue such as SiOC with a thickness in the range of 0.3 to 2 nm (with it being useful in some cases for the total underlayer including the glue layer to have a maximum thickness of less than about 5 nm), and it may be formed or deposited using plasma-based depositions, such as cyclical or non-cyclical PECVD techniques, or other techniques. The adhesion layer may also be useful in improving the adhesion with the photoresist (e.g., layer 206 in structure 200 of FIG. 2 that may be formed in step 110 of method 100 of FIG. 1). The adhesion layer, hence, could be included to act as a sealing layer/film to prevent or limit outgassing while also improving adhesion. This layer also may enable use of more high-z materials, which otherwise may be limited in use as forming potentially toxic layers.

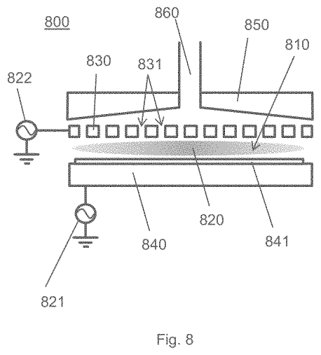

Direct, indirect, and remote plasma depositions can be used as well, either in ALD, CVD, hybrid mode, as shown in with the systems 800, 900, and 1000 in FIGS. 8-10, respectively. Various pulsing schemes featuring super cycles made up of two separate sub-cycles can be used. For example, a PEALD process may tune concentrations or amounts of a desired element using a super cycle process (e.g., sub-cycle 1: In precursor pulse, O reactant pulse; sub-cycle 2: Sn precursor pulse, O reactant pulse; with each repeated as useful for tuning in on a desired amount of any particular element).

FIG. 8 shows a schematic representation of an embodiment of a direct plasma system 800 that is operable or controllable to perform the fabrication processes or methods as described herein. The system 800 includes a reaction chamber 810 in which a plasma 820 is generated. In particular, the plasma 820 is generated between a showerhead injector 830 and a substrate support 840 supporting a substrate or wafer 841.

In the configuration shown, the system 800 includes two alternating current (AC) power sources: a high frequency power source 821 and a low frequency power source 822. In the configuration shown, the high frequency power source 821 supplies radio frequency (RF) power to the showerhead injector, and the low frequency power source 822 supplies an alternating current signal to the substrate support 840. The radio frequency power can be provided, for example, at a frequency of 13.56 MHz or higher. The low frequency alternating current signal can be provided, for example, at a frequency of 2 MHz or lower.

Process gas comprising precursor, reactant, or both, is provided through a gas line 860 to a conical gas distributor 850. The process gas then passes via through holes 831 in the showerhead injector 830 to the reaction chamber 810. Whereas the high frequency power source 821 is shown as being electrically connected to the showerhead injector and the low frequency power source 822 is shown as being electrically connected to the substrate support 840, other configurations are possible as well. For example, in some embodiments (not shown), both the high frequency power source and the low frequency power source can be electrically connected to the showerhead injector; both the high frequency power source and the low frequency power source can be electrically connected to the substrate support; or both the high frequency power source can be electrically connected to the substrate support, and the low frequency power source can be electrically connected to the showerhead injector.

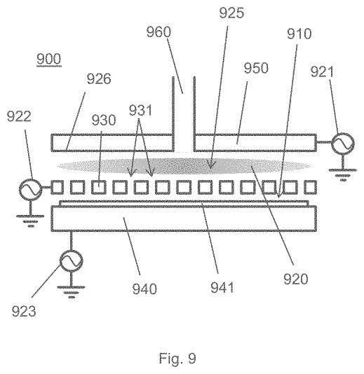

FIG. 9 shows a schematic representation of another embodiment of an indirect plasma system 900 operable or controllable to perform the methods as described herein. The system 900 includes a reaction chamber 910, which is separated from a plasma generation space 925 in which a plasma 920 is generated. In particular, the reaction chamber 910 is separated from the plasma generation space 925 by a showerhead injector 930, and the plasma 920 is generated between the showerhead injector 930 and a plasma generation space ceiling 926.

In the configuration shown, the system 900 includes three alternating current (AC) power sources: a high frequency power source 921 and two low frequency power sources 922, 923 (i.e., a first low frequency power source 922 and a second low frequency power source 923). In the configuration shown, the high frequency power source 921 supplies radio frequency (RF) power to the plasma generation space ceiling, the first low frequency power source 922 supplies an alternating current signal to the showerhead injector 930, and the second low frequency power source 923 supplies an alternating current signal to the substrate support 940. A substrate 941 is provided on the substrate support 940. The radio frequency power can be provided, for example, at a frequency of 13.56 MHz or higher. The low frequency alternating current signal of the first and second low frequency power sources 922, 923 can be provided, for example, at a frequency of 2 MHz or lower.

Process gas comprising precursor, reactant, or both, is provided through a gas line 960 that passes through the plasma generation space ceiling 926 to the plasma generation space 925. Active species such as ions and radicals generated by the plasma 920 from the process gas pass via through holes 931 in the showerhead injector 930 to the reaction chamber 910.

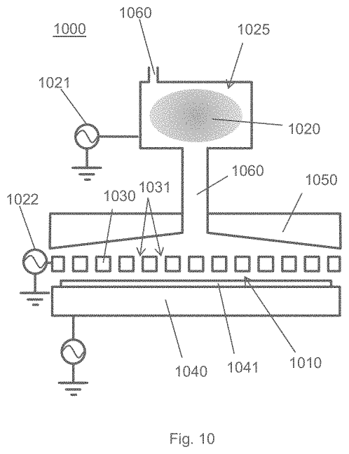

FIG. 10 shows a schematic representation of an embodiment of a remote plasma system 1000 operable or controllable to perform the fabrication methods or processes as described herein. The system 1000 includes a reaction chamber 1010, which is operationally connected to a remote plasma source 1025 in which a plasma 1020 is generated. Any sort of plasma source can be used as a remote plasma source 1025, for example an inductively coupled plasma, a capacitively coupled plasma, or a microwave plasma. In particular, active species are provided from the plasma source 1025 to the reaction chamber 1010 via an active species duct 1060 to a conical distributor 1050 via through holes 1031 in a shower plate injector 1030 to the reaction chamber 1010. Thus, active species can be provided to the reaction chamber in a uniform way.

In the configuration shown, the system 1000 includes three alternating current (AC) power sources: a high frequency power source 1021 and two low frequency power sources 1022, 1023 (e.g., a first low frequency power source 1022 and a second low frequency power source 1023). In the configuration shown, the high frequency power source 1021 supplies radio frequency (RF) power to the plasma generation space ceiling, the first low frequency power source 1022 supplies an alternating current signal to the showerhead injector 1030, and the second low frequency power source 1023 supplies an alternating current signal to the substrate support 1040. A substrate 1041 is provided on the substrate support 1040. The radio frequency power can be provided, for example, at a frequency of 13.56 MHz or higher. The low frequency alternating current signal of the first and second low frequency power sources 1022, 1023 can be provided, for example, at a frequency of 2 MHz or lower.

In some embodiments (not shown), an additional high frequency power source can be electrically connected to the substrate support. Thus, a direct plasma can be generated in the reaction chamber. Process gas comprising precursor, reactant, or both, is provided to the plasma source 1025 by means of a gas line 1060. Active species such as ions and radicals generated by the plasma 1020 from the process gas are guided to the reaction chamber 1010.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

We claim:

1. A method of forming an extreme ultraviolet (EUV) absorber layer on a surface of a substrate, the method comprising the steps of:
providing a substrate within a reaction space of a gas-phase reactor;
providing a precursor to the reaction space;
providing a reactant to the reaction space; and
forming an absorber layer on a surface of the substrate within the reaction space, the absorber layer comprising an element having an EUV cross section (σ_{α}) of greater than 2×10⁶ cm²/mol.

2. The method of claim 1, wherein the absorber layer comprises an oxide of the element.

3. The method of claim 1, wherein the element is selected from the group consisting of: I, Te, Cs, Sb, Sn, In, Bi, Ag, Pb, Au, Pt, and Ir.

4. The method of claim 1, wherein the element is Sn.

5. The method of claim 1, wherein the precursor comprises a compound according to the following formula: M(NR¹R²)ₙ, wherein M is selected from Cs, Sb, Sn, In, Bi, Ag, Pb, Au, Pt, and Ir, wherein R¹ and R² are independently selected from H and C1 to C4 alkyl, and wherein n is from at least 3 to 5.

6. The method of claim 1, wherein the element is In.

7. The method of claim 1, wherein the precursor comprises a compound according to the following formula: MRₙ, wherein M is selected from Cs, Sb, Sn, In, Bi, Ag, Pb, Au, Pt, and Ir, wherein R is a C1 to C4 alkyl, and wherein n is from at least 3 to at most 5.

8. The method of claim 1 wherein the absorber layer further comprises a dopant selected from the group consisting of I, Te, Cs, Sb, Sn, In, Bi, Ag, Pb, Au, Pt, and Ir.

9. The method of claim 1, wherein the absorber layer further comprises a dopant selected from the group consisting of Mn, Fe, Co, Ni, Cu, Zn, Ga, Ge, Hf, and As.

10. The method of claim 8, wherein the absorber layer includes an underlayer and a layer including the dopant overlying or underlying the underlayer.

11. The method of claim 1, wherein the step of forming the absorber layer comprises a cyclical deposition process.

12. The method of claim 1, further comprising forming an EUV photoresist layer overlying the absorber layer.

13. The method of claim 1, wherein the step of forming the absorber layer comprises atomic layer deposition.

14. The method of claim 1, further comprising forming an adhesion layer overlying the absorber layer to limit outgassing from the adhesion layer and facilitate adhesion of the absorber layer to the EUV photoresist layer.

15. The method of claim 16, wherein the adhesion layer comprises SiOC.

16. A structure for forming patterned features using extreme ultraviolet (EUV) radiation, the structure comprising:
a substrate; and
an absorber layer formed overlying the substrate, wherein the absorber layer comprises an oxide of I, Te, Cs, Sb, Sn, In, Bi, Ag, Pb, Au, Pt, or Ir.

17. A structure for forming patterned features using extreme ultraviolet (EUV) radiation, the structure comprising:
a substrate;
an underlayer formed overlying the substrate; and
a dopant layer formed overlying or underlying the underlayer to increase EUV sensitivity, wherein the dopant layer comprises at least one of a moderate EUV absorption dopant with an EUV cross section (σ_{α}) of greater an EUV cross section (σ_{α}) of oxygen and a high EUV absorption dopant with an EUV cross section (σ_{α}) of greater than 2×10⁶ cm²/mol.

18. The structure according to claim 17, wherein the dopant layer comprises at least one of a moderate EUV absorption dopant selected from the group consisting of Mn, Fe, Co, Ni, Cu, Zn, Ga, Ge, Hf, and As.

19. The structure according to claim 18, wherein the high EUV absorption dopant is selected from the group consisting of I, Te, Cs, Sb, Sn, In, Bi, Ag, Pb, Au, Pt, and Ir.

20. The structure according to claim 17, wherein the underlayer comprises an oxide of an element selected from the group consisting of I, Te, Cs, Sb, Sn, In, Bi, Ag, Pb, Au, Pt, and Ir.
